(19) United States
(12) Patent Application Publication
(10) Pub. No.: US 2020/0270119 A1
(43) Pub. Date: Aug. 27, 2020

(54) MICROMECHANICAL COIL DEVICE

(71) Applicant: Sercalo Microtechnology Ltd, Schaan (LI)

(72) Inventors: Vincent Kuenlin, Neuchâtel (CH); Cornel Marxer, Neuchâtel (CH)

(21) Appl. No.: 16/780,647

(22) Filed: Feb. 3, 2020

(30) Foreign Application Priority Data
Feb. 26, 2019 (CH) 00232/19

(51) Int. Cl. B81B 5/00; B81B 3/00

(52) U.S. Cl. CPC B81B 5/00; B81B 3/0045; B81B 2203/058; B81B 2201/04; B81B 2203/0118; B81B 3/0067

(57) ABSTRACT

A micromechanical device includes an actuator moveable along at least one rotational axis, and an electromagnetic type actuating device. The rotor is composed of a wire coil mounted on a moveable frame, which is rotationally integral with the actuator. The coil conducts the electric current. Protruding strands form a loop proximate the torsional beam. In another embodiment, the coil terminates through its two ends located on the moveable frame. The ends of the coil are each welded to one of the metal plates terminating on the moveable frame. Starting from the power supply pads on the fixed frame, the conductive lines transit through the torsional beam to join the ends of coil on the moveable frame. To make several plates going through one of the torsional beams, the beams are isolated electrically by a groove.

### CROSS-REFERENCE TO RELATED APPLICATION

This application claims priority to Swiss Patent Application No. 00232/19 filed Feb. 26, 2019, the entirety of which is incorporated by this reference.

### FIELD OF THE INVENTION

This invention is related to electromechanical microsystems, better known under the appellation MEMS, from the English Micro Electro Mechanical Systems. It concerns more specifically a micromechanical device including a moveable actuator along at least one rotational axis, and actuating means of this actuator of the electromagnetic type.

### SUMMARY OF THE INVENTION

Such devices are generally optical devices in which the actuator is composed of a mirror connected to a fixed frame through two elastic torsional beams defining the mirror's rotational axis. Alternatively, the actuator is moveable along two rotational axes. The mirror is then connected to a first moveable frame using two torsional beams, which is itself connected to the fixed frame through two other torsional beams. Whether moveable along one or two rotational axes, the mirror thus mounted allows diverting a light beam between different fixed angular positions or scanning an angular space using a light beam. Such devices are fitted particularly with optic spectrometers, printers, medical imagery devices, light sensors, and many other devices, including optical control.

Amongst the aforementioned devices, we are interested in the devices activated electromagnetically using a rotor mounted integral rotationally with the actuator, and a stator including two opposite magnetic poles separated by an air gap in which the rotor sits. Such devices, as well as their operation, are described in detail in document EP 2 990 375 B1. More specifically, we are interested here in devices in which the rotor is composed of a wire coil mounted on a moveable frame, which is integral rotationally with the actuator. The moveable frame is connected to a fixed frame through two torsional beams defining the actuator's rotational axis. In such a configuration, the power supply of the coil poses a problem. In fact, the current must be brought from two fixed points; generally two power supply pads on the fixed frame, towards the moveable rotational coil; this without significantly interrupting the movement of the actuator. The difficulty comes here from the respective dimensions of the wire comprising the coil and the torsional beams. The diameter of the wire is generally around one hundred microns, so as to avoid any risk of breakage in installation and in operation. The width of the beams is around fifty microns, for a length in the range of the millimeter, which confers an optimal torsion constant to the beams relative to the torsion forces generated by the rotor and the stator. As a result, with a diameter of the wire equivalent to two-times the length of the torsion beams, the coil wire cannot transit through the torsion beams to reach the power supply pads on the fixed frame, without seriously interrupting the rotation movement of the actuator. In state of the art, the coil wires, therefore, do not go through the torsion beams, but, however, the joint between the coil and the power supply pads is not optimized. The rotationally integral moveable frame of the actuator is generally rectangular, and the wires of the coil protrude from it through any two points. They then join the power supply pads so as not to block the rotational movement of the actuator, but with no more precautions.

Now, thus arranged, the outgoing wires significantly interrupt the rotational movement of the actuator, and in addition, they do this in an uncontrolled and non-reproducible manner. The operation of the micromechanical device is thus impacted at its heart, and it is very difficult to predict the effect of the interference qualitatively and quantitatively. This invention has the goal of remedying this disadvantage by proposing a micromechanical device including a moveable rotational mounted actuator, at least one rotor made up of a wire coil mounted integral rotationally of said actuator, at least one stator and a fixed frame equipped with two power supply pads, in which the connection between the wires of the coil and the power supply pads on the fixed frame is designed in order to minimize the interruptions of the rotational movement of the actuator. More precisely, this invention concerns a micromechanical device with a coil including a fixed frame, a mounted actuator that is moveable along a rotational axis AA on the fixed frame through two axis torsional beams AA, and a rotor made up of a coil of conductive wire mounted integral rotationally with the actuator, said coil being powered in current from the fixed frame via its two terminal wire strands which are a connection to power supply pads arranged on the fixed frame. As per the invention, the dimensions and the geometry of the terminal wires are chosen so that their k_{segments} stiffness constant is small against the kₚ stiffness constant of the beams and so that their I_{segments} rotational inertia moment is small against the actuator's Iₐ rotational moment. Thanks to this arrangement of the terminal wire strands, and as will be shown in the rest of this presentation, the rotational movement of the actuator is minimally impacted by the transit for the current from the fixed frame to the moveable coil in rotation, and the reliability of the micromechanical device within the invention is improved. This invention also concerns a micromechanical coil device including a fixed frame, an integral moveable mounted actuator along a rotational axis AA on the fixed frame through two axis torsional beams AA, and a rotor made up of a coil of conductor wire mounted integral rotationally with the actuator, the coil being supplied with current from the fixed frame via two conductor segments which are connected to power supply pads arranged on the fixed frame. As per the invention, the conductor segments are made up of two metal tracks extending over at least one torsional beam, and the two ends of the coil are each welded to one of the metal tracks on both sides of the torsional beams. The silicon being made insulating through a thin dielectric layer such as silicon dioxide, a silicon nitride, or another thin layer. Thanks to the welding of the ends of the coil to metal plates joining power supply pads onto the fixed frame via the torsional beams, the rotational movement of the actuator is not significantly disrupted by the flow of the current from the fixed frame to the moveable frame.

### BRIEF DESCRIPTION OF THE DRAWINGS

The characteristics and the advantages of this invention will be shown more clearly in the reading of the following description, given only as an example, and given in reference to the appended drawings in which:

FIG. 1 is a schematic top view of a first iteration of a micromechanical coil device as per the invention including a moveable actuator along a rotational axis,

FIG. 2 is a schematic top view of a variant of the first iteration of a micromechanical coil device as per the invention,

FIG. 3 is a schematic top view of the first iteration of a micromechanical coil device as per the invention, including a moveable actuator along two rotational axes,

FIG. 4 illustrates a top view of a second iteration of a micromechanical coil device as per the invention schematically,

FIGS. 5a and 5b are schematic sectional views along an axis BB of the second iteration of a micromechanical coil device in two different stages of the manufacturing process, and

FIG. 6 is a schematic top view of a variant of the second iteration of a micromechanical coil device as per the invention.

### DETAILED DESCRIPTION OF THE INVENTION

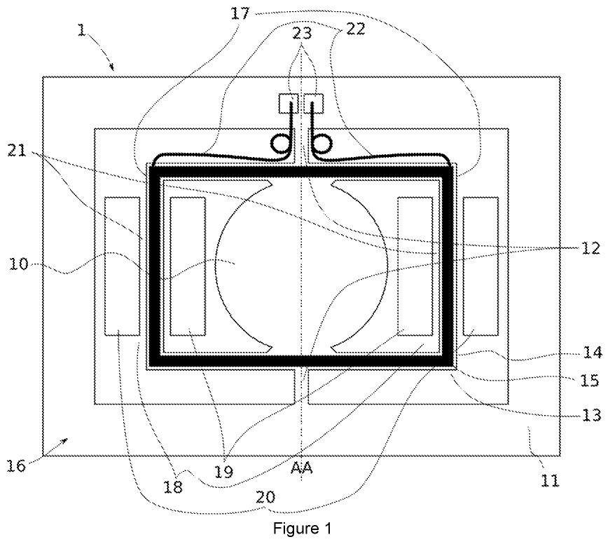

The micromechanical coil device represented in FIG. 1, and referenced as a whole in 1, classically includes an actuator 10, mounted integral rotationally along a rotational axis AA on a fixed frame 11, through two torsional beams 12. Actuator 10 is an optically active element, such as a mirror, a diffraction network, a lens, or any other component intended to interact with a light beam. It is mounted integral rotationally with a rotor 13 made up of a moveable frame 14 topped with a conductor wire coil 15. The unit comprised of actuator 10, fixed frame 11, torsional beams 12 and moveable frame 14 is made of a single component 16 from an SIO (from the English Silicon On Oxide) plate, through photolithography operations, and is known under the appellation MEMS (from the English Micro Electro Mechanical System). The dimension of the unit is around one square centimeter. Classically, rotor 13 is of a generally rectangular or square geometry and includes two sides 17 separate from actuator 10, parallel to the rotational axis AA and symmetrically relative to this same rotational axis AA. Two stators 18 each, including two opposite poles 19, 20 separated from each other by an air gap 21, are arranged in the vicinity of rotor 13 so that each receives a side 17 of rotor 13 in its air gap. The flow of the current into rotor 13, combined with the magnetic field B prevailing in air gaps 21, creates a Laplace force F pulling rotor 13 and rotational actuator 10 around axis AA. As per the application of the micromechanical coil device 1, this rotational movement is done in static or dynamic mode. Whatever the mode of operation chosen, the rotational movement of the actuator 10-beam 12 movement depends on the torque Mₚ of beams 12 and the moment of inertia Iₐ of actuator 10. These values are characteristic of the actuator 10-torsional beams 12 unit and depend on their geometry, the spatial distribution of the mass and the material that comprises them. More specifically, torque Mₚ of beams 12 is related to their stiffness constant kₚ through the following relationship:

Mₚ=2·kₚ·a (1)

where a is the rotational angle of actuator 10. The stiffness constant kₚ is set by the dimensions of the torsional beams 12 and by the elasticity coefficient of the silicon. Thus, the dimensions and the geometry of actuator 10, the torsional beams 12 and the MEMS unit 16 are planned for a determined operation of device 1 for a given application.

Coil 15 is itself made up of a coil of conductor wire, typically copper or aluminum, conforming to the geometry of moveable frame 14. It terminates in its ends by two strands 22 coming out of the coil that contact two power supply pads 23 arranged on fixed frame 11, thus ensuring the flow of the current from the fixed component, fixed frame 11, to the moveable component, rotor 13. The design of coil 15 and of its two protruding strands 22, complies with the mechanical, electrical and geometrical constraints imposed by the operation of device 1. These constraints are the following, in decreasing order of importance: Coil 15 must carry the electric current, the wire must be sufficiently resistant mechanically so as not to break during mounting or in operation, and finally, the two strands 22 of the coil must minimally disrupt the rotational movement of actuator 10. The two first constraints require that the wire be of a conductive metal, typically aluminum or copper and that its diameter be from at least 50 to 100 micrometers (depending on the metal). Under this value, the wire breaks during mounting. As a result, a value of 100 micrometers will be used.

The last constraint is more complex to implement. In fact, the protruding strands 22 of the coil thus have a torque M_{wire} and a moment of inertia I_{wire} in addition respectively to the torque Mₚ of the beams and the moment of inertia Iₐ of actuator 10. In order to disrupt the rotational movement of actuator 10 the least, the arrangement of the protruding wire strands 22 is planned so that the torques M_{wire} and moments of inertia I_{wire} of the wire that sticks out are small against, respectively, the torque of beams Mₚ and the moment of inertia of actuator Iₐ. Initially, the torque of wire M_{wire} is related to its stiffness constant k_{wire} by the relationship (1) such that it takes a minimal value for a minimal stiffness constant k_{wire}. Now the stiffness constant k_{wire} of the wire is low for a long wire length and for a small diameter. The diameter being fixed at 100 micrometers at a minimum because of the mechanical constraints, the length of the protruding wire strands 22 chosen to be long in order to minimize the stiffness constant k_{wire}. By long, we mean a length of at least an order of magnitude greater than the length of the torsional beams 12. In addition, the moment of inertia I_{wire} of the protruding wire strands 22 is minimized for low mass and spread out mainly in the vicinity of the system's rotational axis AA. The mass depends on the length, and the diameter of the protruding wire strands 22 and is therefore set by the previous constraints. Regarding its distribution around axis AA, it is given by the geometry of the protruding wire strands 22, which is optimized in this respect.

By doing the synthesis of the previous elements, we arrive at an optimal arrangement of the protruding wire strands 22: strands 22 come out of coil 15 through two corners of moveable frame 14, symmetrical in relation to axis AA, and contact the power supply pads 22 located on fixed frame 11 symmetrically in relation to axis AA, on both sides of torsional beam 12 adjoining said corners. In addition, protruding strands 22 form a loop in the vicinity of this torsional beam 12. Thus, the length of the protruding strands 22 is long against the length of torsional beams 12, and their center of gravity is near axis AA. As a variant, the protruding strands 22 form a wave pattern in the vicinity of torsional beam 12, or a helix or any other shape that allows returning most of the mass from strands 22 in the vicinity of axis AA. Thus arranged, the protruding wire strands 22 have a low stiffness constant k_{wire} and low moment of inertia I_{wire} against respectively the stiffness constant kₚ of beams 12 and the moment of inertia Iₐ of actuator 10.

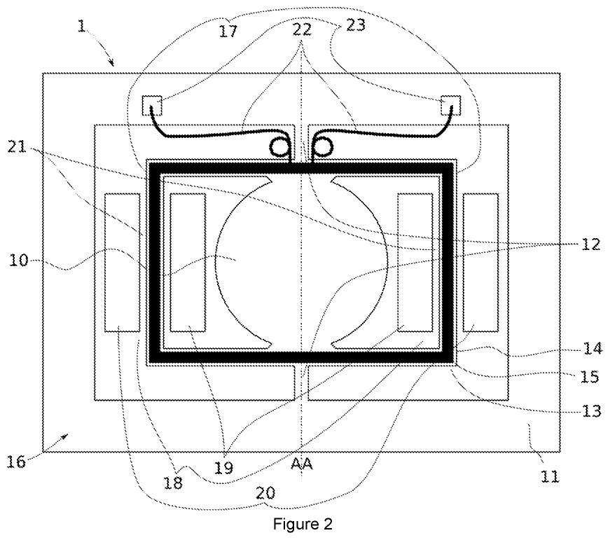

In FIG. 2, we represented a variant of the micromechanical coil device that is distinguished from the iteration represented in FIG. 1 by the positioning of the exit points of strands 22 and power supply pads 23 but behaves identically. In fact, strands 22 come out of coil 15 through two points located symmetrically relative to axis AA, in the immediate vicinity of one of the torsional beams 12, and join power supply pads 23 located on fixed frame 11 symmetrically relative to axis AA away from said torsional beam. As in the previous iteration, the protruding wire strands 22 forms a coil, a wave pattern, or a helix in the vicinity of torsional wire 12. As such, the protruding wires 22 are long relative to the length of torsional beams 12, and their mass is distributed in the vicinity of axis AA. They have characteristics similar to the previous system in terms of stiffness constant and moment of inertia.

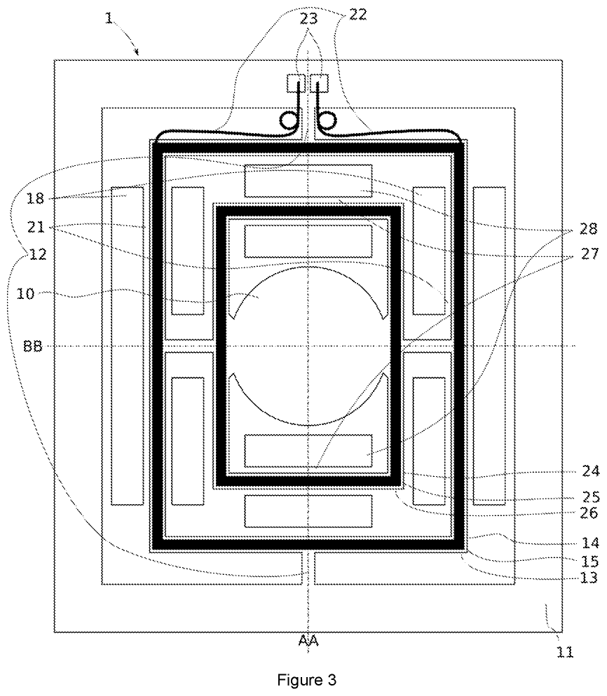

Micromechanical coil device 1 represented in FIGS. 1 and 2 includes a moveable actuator 10 along a rotational axis AA. This invention also applies for a moveable actuator 10 along two rotational axes AA and BB. FIG. 3 illustrates such a micromechanical device 1. Actuator 10 is mounted integral rotationally with a first moveable frame 14, a rotational axis AA, topped with a coil 15, and second moveable frame 24, a rotational axis BB perpendicular to AA, toped with a conductive line 25. The first moveable frame 14 forms with coil 15 a first rotor 13, whereas the second moveable frame 24 forms with the conductive line 25 a second rotor 26. Each of the two rotors 13 and 26 is taken into the air gaps, respectively 21 and 27, of fixed stators 18 and 28, in the way described under FIG. 1. The operation of this micromechanical coil device 1 is similar to the operation of a device with one rotational axis, except that the actuator sweeps against a surface and not a line.

As per the invention, coil 15 ends in two protruding wire strands 22, whose arrangement, dimensions, and geometry are the same as already described under FIGS. 1 and 2. They thus join power supply pads 23 on fixed frame 11 by minimally disrupting the rotational movement of actuator 10 along axis AA. The principle and the functionality of the invention are identical to the principle and functionality of a micromechanical coil device 1 with one rotational axis.

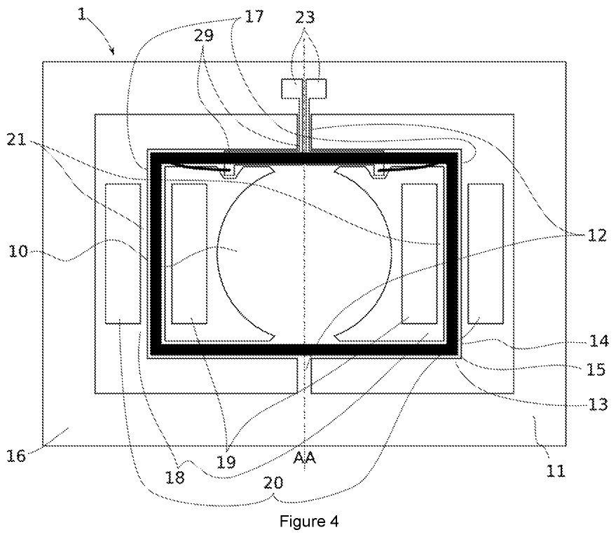

We refer now to FIG. 4, which represents a second iteration of a micromechanical device 1 as per the invention. This second iteration is distinct from the first in that the coil 15 does not include any protruding wire strands 22, but forms a coil extending strictly over the moveable frame 14. Coil 15 terminates in its two ends located on the moveable frame 14 in the immediate vicinity of one of the torsional beams 12. The ends contact two metal plates 29 transiting through torsional beam 12 in order to join the power supply pads 23 on the fixed frame 11. The metallic plates 29 are deposited, for example, through a pulverization process or through a PVD process (from the English Plasma Vapor Deposition) onto torsional beam 12. The ends of coil 15 are welded to the metal plates 29 so that no wire strand protrudes from coil 15. In this iteration, the rotational movement of actuator 10 is not disrupted in any way, whether in static mode or in dynamic mode, because the metal plates are merged with beams 12 and have a negligible stiffness constant kₗᵢₙₑₛ against the stiffness constant of beams 12.

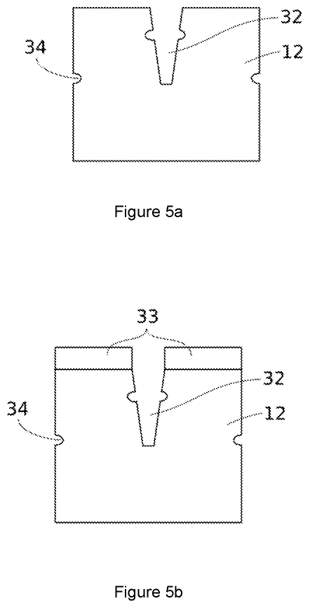

To make several metal plates 29 going through one of the torsional beams 12, it is not possible to use a shadow mask during the depositing of the metal layer, because the distance separating the two plates 29 is around one micron, and the resolution of the shadow mask is about 100 microns, which makes the separation of the two plates 29 impossible. It would then be necessary in principle, to manage to form the two plates 29, to engrave the metal over the entire length of beam 12 and over a length of one micron, through a photolithography process. But this process is long and complex, and in addition, it requires costly installations. This invention proposes to overcome this difficulty through an ingenious process. As already mentioned previously, a photolithography process is used during the manufacturing of micromechanical device 1 from a silicon plate. During this process, actuator 10, fixed frame 11, torsional beams 12, and moveable frame 14 are cut out in the plate on a depth of around 200 microns. We then make use of a process property of RIE engraving (from the English Reactive Ion Etching) in order to prepare, from this stage of the manufacturing of micromechanical device 1, the formation of the two metal plates 29. In fact, the engraving speed of the RIE process varies based on the width of the pattern to be engraved. For a pattern with a width of 1 micron, the etching is around two-times slower than for a pattern with a width of 20 microns and more. We then engrave a thin groove 32 of a width of 2 microns along beam 12 and of a depth of around half the thickness of beam 12, as represented sectionally in FIG. 5a. To make the insulating silicon, we make a thin insulating layer grow of a thickness of around 0.1 um; for example, through thermal oxidation or through another process well known by skilled persons.

During the stage of metal depositing on micromechanical device 1, metal 33 is deposited on both sides of groove 32 but not inside it because of the low ratio between the width of groove 32 and its depth. This phenomenon is illustrated in FIG. 5b. We thus made two metal plates 29 running over one of the torsional beams 12, by eliminating the need for the photolithography stage of metal layer 33. By construction, metal plates 29 are separated and isolated through a groove 32 of a depth greater than 5 times its width.

We observe that the RIE engraving process is directional; this is why the engraved walls of beam 12 and groove 32 are essentially vertical. A short stage of isotropic engraving may, however, be performed around over half of the engraving in order to make a small notch 32 in the engraved wall. This notch 32 allows avoiding any potential short circuit between metal plates 29, which could happen if a very low quantity of metal is deposited inside groove 32. Notch 34 interrupts the potential thin metal layer formed along the walls of groove 32.

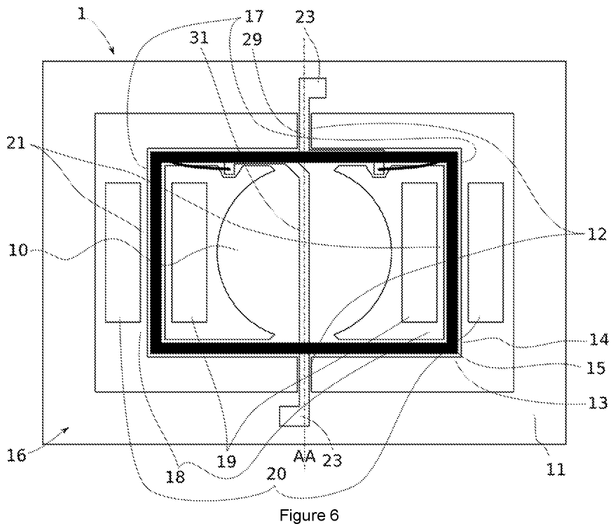

In certain cases, it may prove impossible to make two metal plates transit through the same torsional beam. In fact, on the basis of the current required for the operation of micromechanical coil device 1, metal plates 29 may be too wide to extend parallelly over the width of 50 micrometers of a torsional beam 12. But coil 15 must make a whole number of coils over moveable frame 14 so that the mass of the wire is distributed symmetrically with regard to rotational axis AA. As a result, the two ends of coil 15 are necessarily located in the vicinity of the same torsional beam 12, and it is not possible to make one of the metal plates 29 transit through a first beam 12 and the other through the second beam 12. The solution to this difficulty is illustrated in FIG. 6. On this variant of the second iteration of micromechanical device 1, coil 15 forms, on moveable frame 14, a coil whose two ends are located in the vicinity of one of the torsional beams 12. A first end is connected to a first metal plate 29, which transits through the closest torsional beam 12, whereas a second end is connected to a second metal plate 31, which joins the opposite torsional beam 12 via actuator 10. Let us note that coil 15 and metal plates 29, 31 are located at the rear of the active side of actuator 10, which avoids any interaction between a light beam and conductor line 31. Thanks to this arrangement, each of the torsional beams 12 only supports one metal plate 29, 31, and the mass of the unit is distributed symmetrically along rotational axis AA, it being understood that the mass of the conductive lines 29, 31 is negligible against the mass of moveable frame 14 and coil 15. Metal plates 29, 31 are thus of a wide that may be close to the width of torsional beams 12 and may transport a more significant current than in the variant represented in FIG. 4.

A micromechanical coil device has thus been described. Certainly, this invention is not limited to the iterations described above, but extends to all variants within the means of skilled persons, becoming part of the claims below.

What is claimed is:

1. A micromechanical coil device, comprising:
a fixed frame;
an actuator mounted integrally along a rotational axis on the fixed frame through two axis torsional beams; and
a rotor comprising a coil of conductor wire mounted integral rotationally with the actuator, the coil powered by current from the fixed frame via two terminal wire strands that are connected to power supply pads on the fixed frame, dimensions and geometry of the two terminal wire strands selected so that a segment stiffness constant is relatively low compared to a torsional beam stiffness constant and so that a rotational moment of inertia and a torque is relatively low compared to an actuator torque.

2. The micromechanical coil device of claim 1, wherein the two terminal wire strands are long compared to a length of the two axis torsional beams and wherein a center of gravity of the two terminal wire strands approaches a maximum of the rotational axis.

3. The micromechanical coil device of claim 1, wherein the coil forms a rectangle symmetrically arranged relative to the axis, and the two terminal wire strands protrude from the coil through two corners of the rectangle that are symmetrical in relation to the axis, and wherein the power supply pads are located on the fixed frame symmetrically in relation to the axis on both sides of one of the two axis torsional beams adjoining the corners.

4. The micromechanical coil device of claim 1, wherein the coil forms a rectangle symmetrically arranged relative to the axis, and the two terminal wire strands protrude from the coil through two points located symmetrically in relation to the axis, in a vicinity of one of the torsional beams, and wherein the power supply pads are located on the fixed frame symmetrically in relation to the axis away from the one of the torsional beams.

5. The micromechanical coil device of claim 1, wherein the two terminal wire strands form a loop in a vicinity of one of the torsional beams.

6. The micromechanical coil device of one of claim 1, wherein the two terminal wire strands form a helix in a vicinity of one of the torsional beams.

7. The micromechanical coil device of claim 1, wherein the two terminal wire strands form a wave pattern in a vicinity of one of the torsional beams.

8. The micromechanical coil device, of claim 7, further comprising first and second metal plates that extend over one of the axis torsional beams and are isolated electrically from each other through a longitudinal groove formed in the one of the axis torsional beams.

9. The micromechanical coil device of claim 8, wherein walls of the longitudinal groove form a notch at around mid-depth of the longitudinal groove.

10. The micromechanical coil device of claim 8, wherein a first end of the coil is welded to the first metal plate and a second end of the coil is welded to a second metal plate on an opposite side of the two axis torsional beams, the first and second metal plates extending over a respective one of the two axis torsional beams, and wherein the second metal plate joins an opposite one of the two axis torsional beams via the actuator.

11. The micromechanical coil device of claim 1, wherein the actuator is moveable along two rotational axes.

12. A micromechanical coil device, comprising:
a fixed frame;
an actuator integrally mounted along a rotational axis on a fixed frame through two axis torsional beams; and
a rotor made comprising a coil of conductor wire integrally mounted rotationally with the actuator, the coil being powered by current from the fixed frame via two conductor segments which are connected to power supply pads positioned on the fixed frame, wherein conductor segments are comprised of first and second metal plates extending over at least one torsional beam and wherein ends of the coil are each welded to a respective one of the first and second metal plates and on opposite sides of the two axis torsional beams on a moveable frame.

13. The micromechanical coil device of claim 12, wherein the coil forms a rectangle symmetrically arranged relative to the axis.

14. The micromechanical coil device, of claim 12, wherein the first and second metal plates are isolated electrically from each other through a longitudinal groove formed in the one of the axis torsional beams.

15. The micromechanical coil device of claim 14, wherein walls of the longitudinal groove form a notch at around mid-depth of the longitudinal groove.

16. The micromechanical coil device of claim 12, wherein a first end of the coil is welded to the first metal plate and the second end of the coil is welded to the second metal plate on an opposite side of the two axis torsional beams, the first and second metal plates extending over a respective one of the two axis torsional beams, and wherein the second metal plate joins an opposite one of the two axis torsional beams via the actuator.

17. The micromechanical coil device of claim 12, wherein the actuator is moveable along two rotational axes.
